(19) United States
(12) Patent Application Publication
(10) Pub. No.: US 2025/0167076 A1
(43) Pub. Date: May 22, 2025

(54) BACKSIDE PLACEHOLDERS AND SELF ALIGNED BACKSIDE CONTACTS

(71) Applicant: INTERNATIONAL BUSINESS MACHINES CORPORATION, ARMONK, NY (US)

(72) Inventors: Ruilong Xie, Niskayuna, NY (US); Richard C. Johnson, Selkirk, NY (US); Nicolas Jean Loubet, GUILDERLAND, NY (US); Dureseti Chidambarrao, Weston, CT (US)

(21) Appl. No.: 18/510,748

(22) Filed: Nov. 16, 2023

(51) Int. Cl. H01L 23/48; H01L 27/092; H01L 29/06; H01L 29/423; H01L 29/775; H01L 29/786

(52) U.S. Cl. CPC H01L 23/481; H10D 30/43; H10D 30/6735; H10D 30/6757; H10D 62/115; H10D 62/121; H10D 84/85

(57) ABSTRACT

A semiconductor structure including first shallow trench isolation regions and second shallow trench isolation regions, where the second shallow trench isolation regions are deeper than the first shallow trench isolation regions, and backside contact structures in direct contact with and physically separated by at least one of the second shallow trench isolation regions.

### BACKGROUND

The present invention generally relates to semiconductor structures, and more particularly to nanosheet transistor structures having backside placeholders and self-aligned backside contacts.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include first shallow trench isolation regions and second shallow trench isolation regions, where the second shallow trench isolation regions are deeper than the first shallow trench isolation regions, and backside contact structures in direct contact with and physically separated by at least one of the second shallow trench isolation regions.

According to another embodiment of the present invention, a semiconductor structure is provided. The semiconductor structure may include first shallow trench isolation regions and second shallow trench isolation regions, where the second shallow trench isolation regions are deeper than the first shallow trench isolation regions, a first backside contact structure in direct contact with at least one of the first shallow trench isolation regions and at least one of the second shallow trench isolation regions, and a second backside contact structure in direct contact with at least one of the first shallow trench isolation regions and at least one of the second shallow trench isolation regions, where at least one of the second shallow trench isolation regions physically separates the first backside contact structure from the second backside contact structure.

According to another embodiment of the present invention, a semiconductor structure is provided. The semiconductor structure may include a first shallow trench isolation region arranged between two N-type transistor devices, a second shallow trench isolation region arranged between two P-type transistor devices, a third shallow trench isolation region arranged between and the two N-type devices and the two P-type transistor devices, where the third shallow trench isolation region is deeper than both the first shallow trench isolation region and the second shallow trench region, a first backside contact structure in direct contact with both of the two N-type transistor devices, and a second backside contact structure in direct contact with at least one of the two P-type transistor devices.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a top view of a generic structure is shown to provide spatial context to the different cross-sectional views and structural orientations of the semiconductor structures shown in the subsequent figures;

FIGS. 2 and 3 are cross-sectional views of the semiconductor structure during an intermediate step of a method of fabricating nanosheet transistor structures according to an exemplary embodiment;

FIGS. 4 and 5 are cross-sectional views of the semiconductor structure after patterning the nanosheet layers and the substrate according to an exemplary embodiment;

FIGS. 6 and 7 are cross-sectional views of the semiconductor structure after forming a second mask and recessing some of the first openings according to an exemplary embodiment;

FIGS. 8 and 9 are cross-sectional views of the semiconductor structure after forming first shallow trench isolation regions and second shallow trench isolation regions according to an exemplary embodiment;

FIGS. 10 and 11 are cross-sectional views of the semiconductor structure after forming and patterning a sacrificial gate dielectric and sacrificial gates, forming sidewall spacers. removing portions of the nanosheet layers, and forming inner spacers according to an exemplary embodiment;

FIGS. 12 and 13 are cross-sectional views of the semiconductor structure after forming protective liners and forming placeholder cavities according to an exemplary embodiment;

FIGS. 14 and 15 are cross-sectional views of the semiconductor structure after forming sacrificial placeholders in the placeholder cavities according to an exemplary embodiment;

FIGS. 16 and 17 are cross-sectional views of the semiconductor structure after removing the protective liners and forming source drain regions according to an exemplary embodiment;

FIGS. 18 and 19 are cross-sectional views of the semiconductor structure after forming a dielectric layer, forming gate structures, and gate cut insulators according to an exemplary embodiment;

FIGS. 20 and 21 are cross-sectional views of the semiconductor structure after forming source drain contacts, a middle-of-line and back-end-of-line, and attaching a carrier wafer according to an exemplary embodiment;

FIGS. 22 and 23 are cross-sectional views of the semiconductor structure after flipping the assembly and recessing the substrate according to an exemplary embodiment;

FIGS. 24 and 25 are cross-sectional views of the semiconductor structure after removing remaining portions of the substrate according to an exemplary embodiment;

FIGS. 26 and 27 are cross-sectional views of the semiconductor structure after forming a backside dielectric layer according to an exemplary embodiment;

FIGS. 28 and 29 are cross-sectional views of the semiconductor structure after forming a backside contact mask according to an exemplary embodiment;

FIGS. 30 and 31 are cross-sectional views of the semiconductor structure after forming backside contact trenches according to an exemplary embodiment; and

FIGS. 32 and 33 are cross-sectional views of the semiconductor structure after removing exposed portions of the sacrificial placeholders, forming backside contact structures and backside wiring layers according to an exemplary embodiment;

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As semiconductor devices continue to decrease in size, it has become desirable to provide distances between the near-most nFET and pFET active regions (i.e., the “N2P space”) on the order of about 8 nanometers (nm) to about 30 nm. Providing N2P spaces at these dimensions can present challenges to communicating with the pFET section and the nFET section. Specifically, N2P spaces on this order reduce the process window within which contact structures connecting the nFET section and pFET section could electrically short with one another. Although the process window can be broadened by positioning the contact structures at locations laterally offset from the N2P space, doing so increases the electrical resistance between the contact structures and the respective pFET section and nFET section, thereby offsetting any improvement in process window and/or electrical characteristics of the multilayer IC device.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, using shallow STI at cell boundary and deep STI at N2P space, we enable self-aligned isolation between backside contacts. Doing so enables larger backside contacts which in turn have lower resistance. Additionally, the shallow STI at cell boundary allows for merged backside contacts.

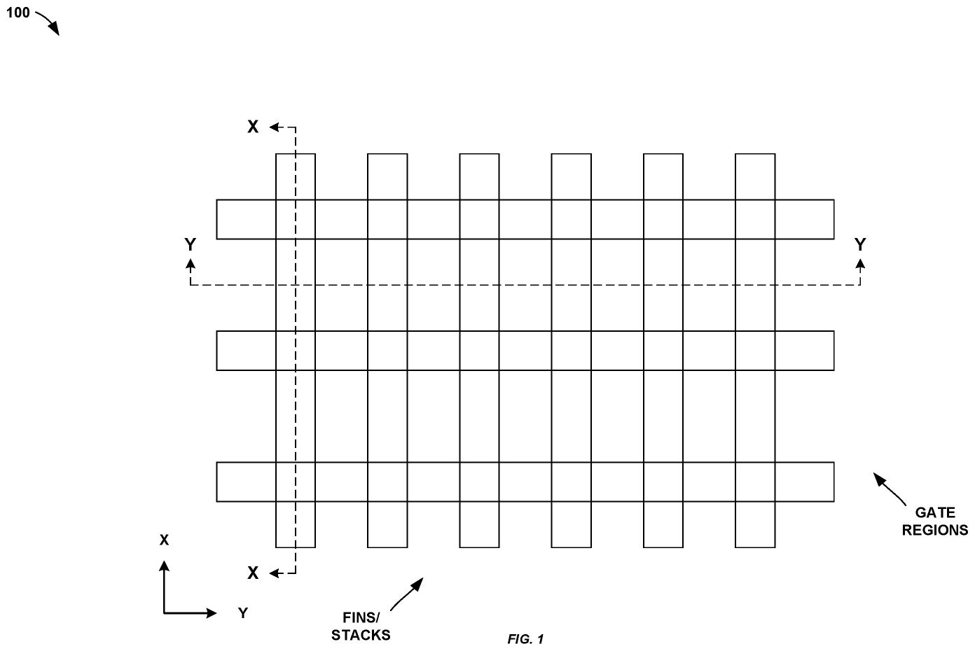

The present invention generally relates to semiconductor structures, and more particularly to nanosheet transistor structures having backside placeholders and self-aligned backside contacts. More specifically, the nanosheet transistor structures and associated method(s) disclosed herein enable a novel solution for providing backside placeholders and self-aligned backside contacts together with small N2P space. Exemplary embodiments of nanosheet transistor structures having backside placeholders are described in detail below by referring to the accompanying drawings in FIGS. 1 to 33. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-33 represent cross section views oriented as indicated in FIG. 1

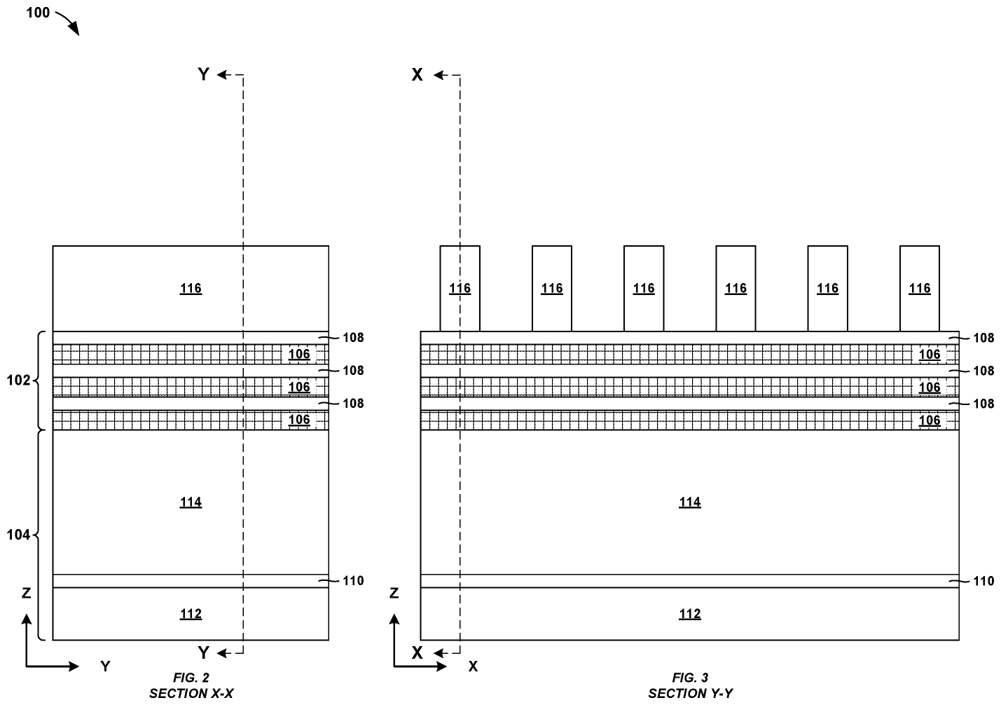

Referring now to FIGS. 2 and 3, a structure 100 is shown during an intermediate step of a method of fabricating nanosheet transistor structures having backside placeholders and self-aligned backside contacts according to an embodiment of the invention. FIG. 2 depicts a cross-sectional view of the structure 100 shown in FIG. 3 taken along line X-X, and FIG. 3 depicts a cross-sectional view of the structure 100 shown in FIG. 2 taken along line Y-Y.

The structure 100 illustrated in FIGS. 2-3 includes nanosheet layers 102 formed on a substrate 104. The nanosheet layers 102 include an alternating series of silicon germanium (SiGe) sacrificial nanosheets 106 (hereinafter “sacrificial nanosheets 106”) and silicon (Si) channel nanosheets 108 (hereinafter “channel nanosheets 108”), as illustrated. Although only a limited number of nanosheet layers 102 are shown, one or more additional nanosheet layers and/or nanosheets can optionally be epitaxially grown in an alternating fashion, and the properties of any additional nanosheets are the same as the corresponding nanosheets described herein.

In one or more embodiments, the nanosheet layers 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, the channel nanosheets 108 of the nanosheet layers 102 may be doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 104 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 104 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure.

A first hard mask 116 is formed on top of the nanosheet layers 102 according to known techniques. Specifically, for example, the first hard mask 116 can be formed by first depositing the hard mask material (for example silicon nitride) onto the topmost layer of the nanosheet layers 102 using, for example, chemical vapor deposition (CVD), plasma enhanced CVD (PECVD) or any suitable technique for dielectric deposition that does not induce a physical or chemical change to the topmost layer of the nanosheet layers 102. The hard mask material is subsequently patterned into a plurality of the hard masks 116 or alternatively individual masks. Patterning the hard mask material is commensurate with a desired footprint and location of the fork sheet device structure.

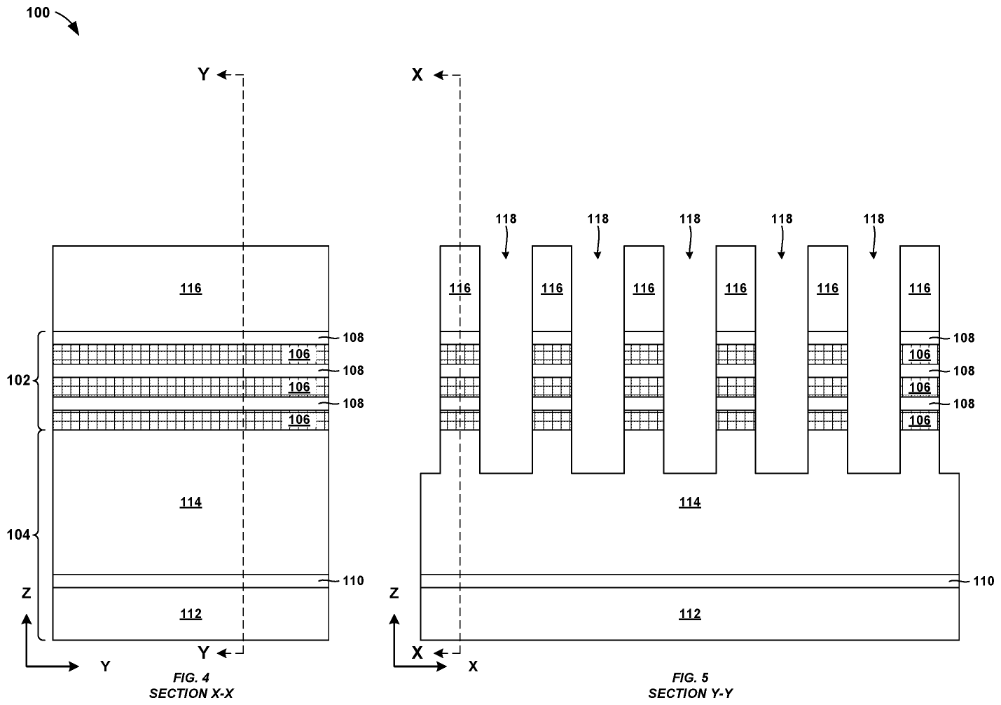

Referring now to FIGS. 4 and 5, a structure 100 is shown after patterning the nanosheet layers 102 and the substrate 104 according to an embodiment of the invention. FIG. 4 depicts a cross-sectional view of the structure 100 shown in FIG. 5 taken along line X-X, and FIG. 5 depicts a cross-sectional view of the structure 100 shown in FIG. 4 taken along line Y-Y.

A directional anisotropic etching technique may be used to remove portions of the nanosheet layers 102 and the substrate 104 according to known techniques. Said differently, the pattern created by the first hard mask 116 is transferred into the nanosheet layers 102 and the substrate 104, as illustrated. In doing so, portions of the sacrificial nanosheets 106, the channel nanosheets 108 and the top semiconductor layer 114 are removed selective to the first hard mask 116, as illustrated. In an embodiment, portions of the nanosheet layers 102 and the substrate 104 are removed using an anisotropic etching technique such as, for example, reactive ion etching. Doing so may require a series of multiple etching steps using different etch chemistries as is well known in the art. Etching is designed to define active regions, create first openings 118, and expose ends of individual nanosheet layers. In all cases, etching continues until at least a portion of the top semiconductor layer 114 is removed a minimum depth sufficient for subsequent creation of a shallow trench isolation regions. In at least an embodiment, the first openings 118 extend a first depth into the top semiconductor layer 114 approximately 20-40 nm into the top semiconductor layer 114.

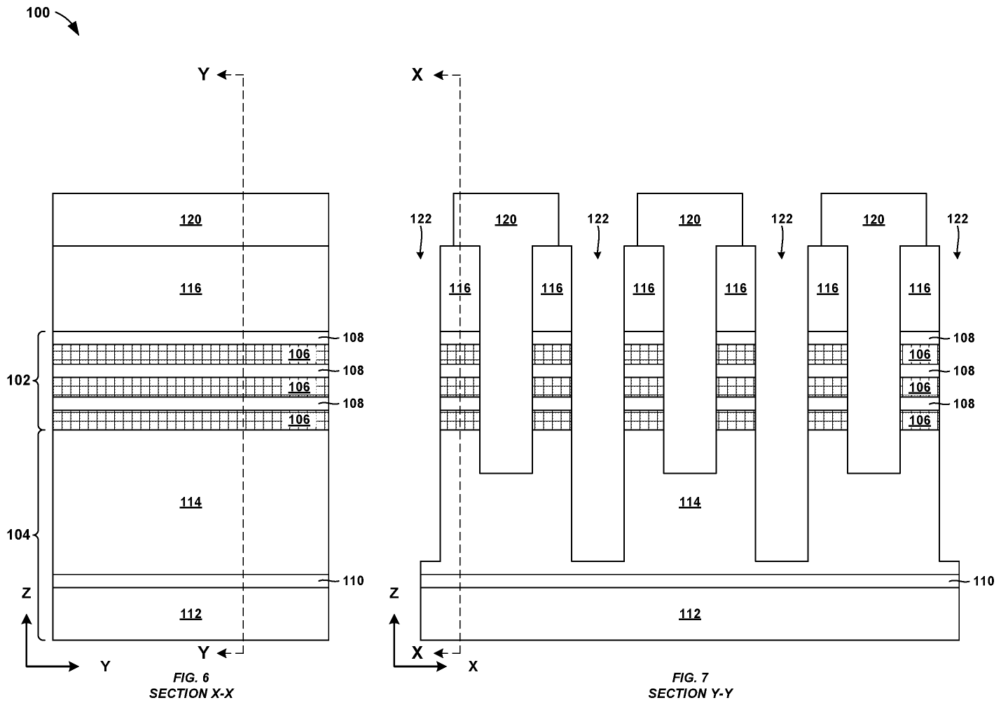

Referring now to FIGS. 6 and 7, a structure 100 is shown after forming a second mask 120 and recessing some of the first openings 118 according to an embodiment of the invention. FIG. 6 depicts a cross-sectional view of the structure 100 shown in FIG. 7 taken along line X-X, and FIG. 7 depicts a cross-sectional view of the structure 100 shown in FIG. 6 taken along line Y-Y.

First, the second mask 120 is deposited and subsequently patterned to expose spaces between NFETs and PFETs of the structure 100 according to known techniques. Specifically, portions of the second mask 120 typically cover or protect every other of first openings 118, as illustrated.

The second mask 120 can be an organic planarization layer (OPL) or a layer of material that is capable of being planarized or etched by known techniques. In an embodiment, for example, the second mask 120 can be an amorphous carbon layer able to withstand subsequent processing temperatures. The second mask 120 can preferably have a thickness sufficient to cover existing structures. After deposition of the second mask 120, a dry etching technique is applied to pattern the second mask 120 according to known techniques.

Next, the first openings 118 left exposed by the second mask 120 are recessed according to known techniques. Specifically, the exposed portions of the top semiconductor layer 114 are removed using an anisotropic etching technique such as, for example, reactive ion etching. Etching is designed to further recess some of the pre-existing first openings 118 not otherwise protected by the second mask 120 to create second openings 122.

In all cases, etching continues until the top semiconductor layer 114 in the exposed regions is further recessed to a second depth greater than the first depth of the first openings 118. In at least an embodiment, the second openings 122 extend a depth into the top semiconductor layer 114 equal to approximately 60-120 nm into the top semiconductor layer 114. As such, the second openings 122 are deeper than the first openings 118. In general, the first openings 118 may be arranged between devices of a similar type, for example, N-type or P-type, and the second openings 122 may be arranged between devices of a different type. As illustrated, the second openings 122 may be arranged between groups of different type devices. In all cases, the second openings 122 do not pierce through the top semiconductor layer 114, and thus do not expose the etch stop layer 110. Finally, the remaining portions of the second mask 120 are removed according to known techniques, for example, by ashing.

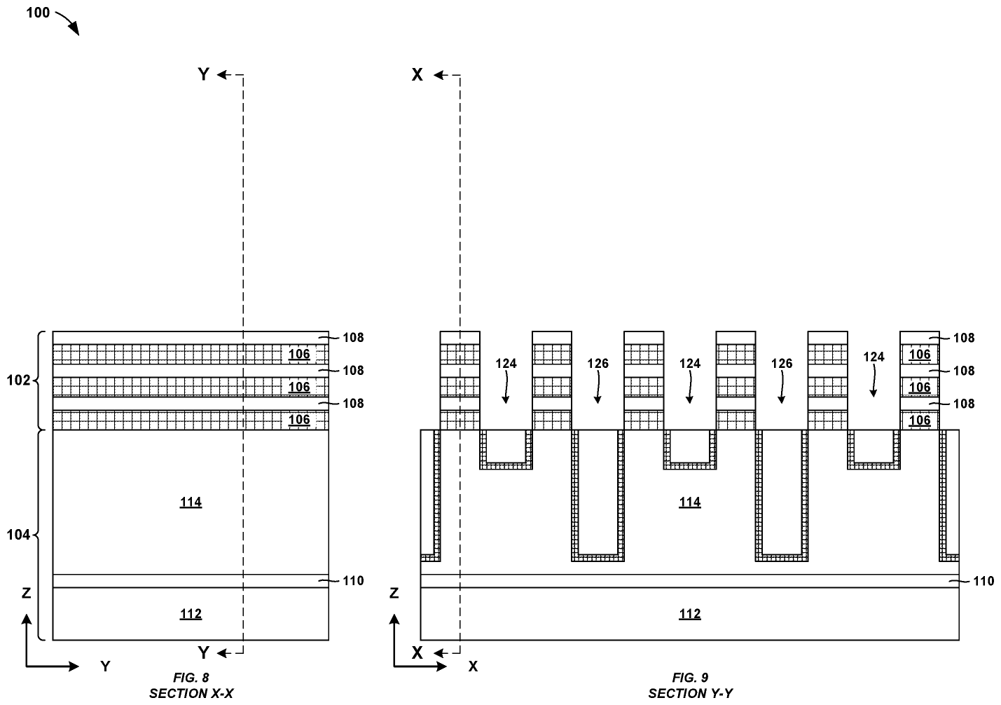

Referring now to FIGS. 8 and 9, a structure 100 is shown after forming first shallow trench isolation regions 124 and second shallow trench isolation regions 126 according to an embodiment of the invention. FIG. 8 depicts a cross-sectional view of the structure 100 shown in FIG. 9 taken along line X-X, and FIG. 9 depicts a cross-sectional view of the structure 100 shown in FIG. 8 taken along line Y-Y.

The first shallow trench isolation regions 124 and the second shallow trench isolation regions 126 (hereinafter collectively referred to as “STI regions 124,126”) are formed according to known techniques. The STI regions 124, 126 are formed at the bottom of the first opening 118 and the second opening 122 formed to isolate adjacent devices from one another according to known techniques. Specifically, a suitable dielectric liner is first conformally deposited followed by a suitable dielectric fill. In an embodiment, the dielectric liner is a nitride, such as silicon nitride, and the dielectric fill is an oxide, such as silicon oxide. After depositing the dielectric liner and the dielectric fill, both materials are etched or recess such that a topmost surface of the STI regions 124,126 is approximately flush with a topmost surface of the top semiconductor layer 114.

Like with the first and second openings described above, the first shallow trench isolation regions 124 may be arranged between devices of a similar type, for example, N-type or P-type, and the second shallow trench isolation regions 126 may be arranged between devices of a different type. As illustrated, the second shallow trench isolation regions 126 may be arranged between groups of different type devices. In all cases, the second shallow trench isolation regions 126 extend deeper into the substrate 104 than the first shallow trench isolation regions 124.

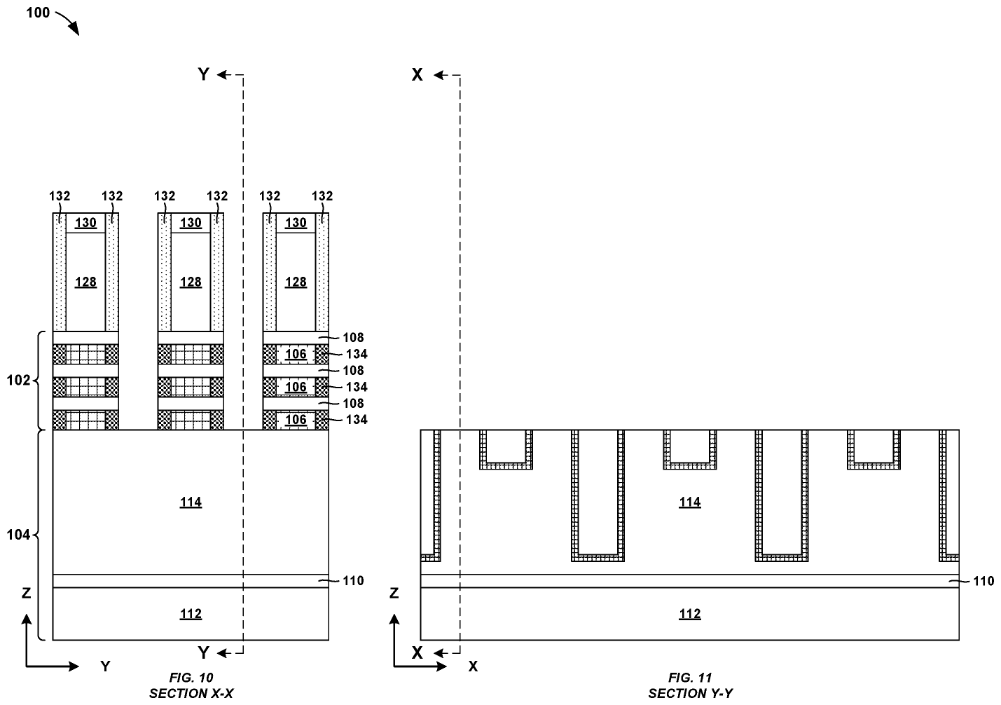

Referring now to FIGS. 10 and 11, a structure 100 is shown after forming and patterning a sacrificial gate dielectric (not shown) and sacrificial gates 128, forming sidewall spacers 132, removing portions of the nanosheet layers 102, and forming inner spacers 134 according to an embodiment of the invention. FIG. 10 depicts a cross-sectional view of the structure 100 shown in FIG. 11 taken along line X-X, and FIG. 11 depicts a cross-sectional view of the structure 100 shown in FIG. 10 taken along line Y-Y.

The sacrificial gate dielectric is deposited directly on exposed surfaces of the structure 100 according to known techniques. Specifically, for example, a relatively thin layer of silicon oxide (SiO₂) is first conformally deposited over and around the nanosheet layers 102, as illustrated.

A sacrificial gate material is then blanket deposited over and around the nanosheet layers 102 according to known techniques. Specifically, for example, a relatively thick layer of amorphous silicon is blanket deposited directly on the sacrificial gate dielectric, as illustrated. In this manner, both the sacrificial gate dielectric and the sacrificial gate material completely cover the nanosheet layers 102, as illustrated.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

Next, a gate hard mask is formed over the structure 100. The gate hard mask defines gate regions of individual devices. According to an exemplary embodiment, the gate hard mask material is deposited onto the sacrificial gate material and then patterned into a plurality of individual gate hard masks 130. Next, the pattern created by the individual gate hard masks 130 is transferred into the sacrificial gate dielectric and the sacrificial gate material forming the sacrificial gates 128, as illustrated. Specifically, portions of sacrificial gate dielectric and the sacrificial gate material are etched or removed selective to the individual gate hard masks 130 typically without etching any of the nanosheet layers 102. According to an embodiment, the portions of the sacrificial gate dielectric and the sacrificial gate material can be removed using a silicon RIE process.

Next, the sidewall spacers 132 are formed by first depositing a conformal layer of dielectric material on top of the structure 100 according to known techniques. Specifically, the layer of dielectric material may be deposited directly on sidewalls of the sacrificial gates 128, sidewalls of the individual gate hard masks 130, and exposed surfaces of the nanosheet layers 102. In an embodiment, the layer of dielectric material can include, for example, silicon nitride or silicon oxide, or SiOCN, SiC, TiOx, AlOx, etc. It may be preferable, in some cases, to fabricate the sidewall spacers 132 from a material having a substantially different etch rate than that of the surrounding materials effect good etch selectivity. In an embodiment, the layer of dielectric material may preferably include an oxide, for example, silicon oxide. The layer of dielectric material can be deposited with a conformal deposition technique, using any known atomic layer deposition technique, molecular layer deposition techniques, or other known conformal deposition techniques. In an embodiment, the layer of dielectric material can have a substantially conformal and uniform thickness ranging from about 5 nm to about 20 nm, and ranges there between.

Next, a directional anisotropic etching technique may be used to remove portions of the layer of dielectric material from horizontal surfaces of the structure 100, while leaving it on the sidewalls of the sacrificial gates 128 and the sidewalls of the individual gate hard masks 130. For example, a reactive-ion-etching technique may be used to remove portions of the layer of dielectric material from directly above the nanosheet layers 102 and from a top surface of the individual gate hard masks 130. The portions of the layer of dielectric material remaining along opposite sidewalls of the sacrificial gates 128 and the individual gate hard masks 130, form the sidewall spacers 132. Furthermore, the individual gate hard masks 130 and the sidewall spacers 132 should each include materials that would allow the individual gate hard masks 130 to be subsequently removed selective to the sidewall spacers 132. Here, it should also be noted that the sidewall spacers 132 depicted in the figures are for illustration purposes and generally can have a slightly different shape from those shown. For example, the sidewall spacers 132 can have rounded corners which may naturally form during the directional etching process as is known in the art.

The sidewall spacers 132 may have a lateral width substantially equal to the conformal thickness of the layer of dielectric material above. In an embodiment, the lateral width of the sidewall spacers 132 may preferably be sublithographic, or smaller than a lithographic minimum dimension. The term “sublithographic” may refer to a dimension or size less than current dimensions achievable by photolithographic processes, and the term “lithographic” or “lithographic minimum dimension” may refer to a dimension or size equal to or greater than current dimensions achievable by photolithographic processes. The sublithographic and lithographic dimensions may be determined by a person of ordinary skill in the art at the time the application is filed. While a “lithographic minimum dimension” and a “sublithographic dimension” are defined only in relation to a lithography tool and normally change from generation to generation of semiconductor technology, it is understood that the lithographic minimum dimension and the sublithographic dimension are to be defined in relation to the best performance of lithography tools available at the time of semiconductor manufacturing. As of 2015, the lithographic minimum dimension is about 20 nm and is expected to shrink in the future. In an embodiment, for example, the sidewall spacers 132 may have a lateral width ranging from about 5 nm to about 15 nm, and ranges there between. It is possible to adjust spacer width based on etch bias or loss of material during process to meet final technology target dimension. The sidewall spacers 132 help define a “fin pattern” or active regions which may subsequently be transferred into underlying layers, including the nanosheet layers 102 and the substrate 104.

Next, individual nanosheet stacks are formed by removing portions of the nanosheet layers 102 according to known techniques. Specifically, the pattern created by the individual gate hard masks 130 and the sidewall spacers 132 is transferred into the nanosheet layers 102. In doing so, portions of the sacrificial nanosheets 106 and the channel nanosheets 108 are removed, as illustrated.

In an embodiment, portions of the nanosheet layers 102 are removed using an anisotropic etch such as, for example, reactive ion etching. Doing so may require a series of multiple etching steps using different etch chemistries as is well known in the art. Etching is designed to define source drain regions and expose ends of individual nanosheet layers. In all cases, etching continues until the topmost surface of the substrate 104 is exposed, as illustrated.

Finally, the sacrificial nanosheets 106 are laterally recessed to make room for the inner spacers 134. In one or more embodiments, the sacrificial nanosheets 106 are laterally recessed using a hydrogen chloride (HCl) gas isotropic etch process, which etches silicon germanium without attacking silicon. In other embodiments, the sacrificial nanosheets 106 are laterally recessed using a CIF3 etch process. Cavities (not shown) are formed by spaces that were occupied by the removed portions of the sacrificial nanosheets 106.

The inner spacers 134 are formed by first conformally depositing a conformal spacer material over the structure 100 to fill the cavities created by laterally recessing the sacrificial nanosheets 106. The conformal spacer material is then isotropically etched to remove all portions except those remaining in the cavities and forming the inner spacers 134. In one or more embodiments, the inner spacers 134 are made from a nitride containing material, for example silicon nitride (SiN). Although the inner spacers 134 are commonly made from a nitride containing material, they can be formed from any material which offers selectivity for subsequent device fabrication operations. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the inner spacers 134 can be selected based on a selectivity of subsequent device fabrication operations for the selected material being below a predetermined threshold.

The inner spacers 134 are positioned such that subsequent etching processes used to remove the sacrificial nanosheets 106 during device fabrication do not also attack subsequently formed source drain regions.

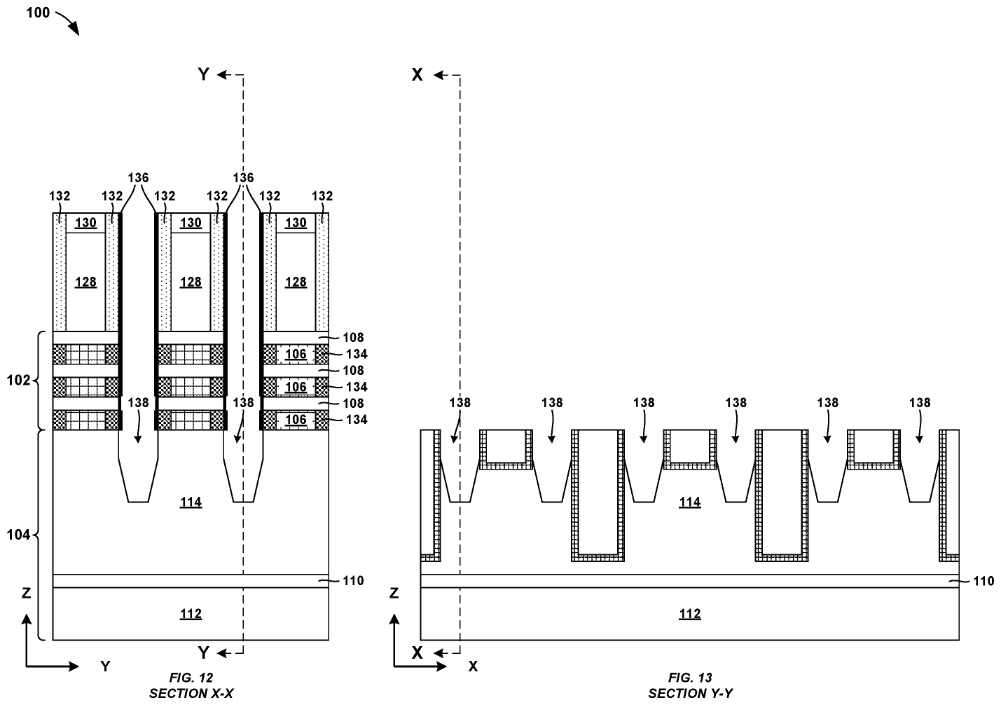

Referring now to FIGS. 12 and 13, a structure 100 is shown after forming protective liners 136 and forming placeholder cavities 138 according to an embodiment of the invention. FIG. 10 depicts a cross-sectional view of the structure 100 shown in FIG. 11 taken along line X-X, and FIG. 11 depicts a cross-sectional view of the structure 100 shown in FIG. 10 taken along line Y-Y.

The protective liners 136 are formed by first depositing a conformal dielectric layer on top of the structure 100 according to known techniques. Specifically, the conformal dielectric layer may be deposited directly on sidewalls of the sidewall spacers 132, the channel nanosheets 108, and the inner spacers 134. In an embodiment, the conformal dielectric layer can include, for example, SiN, AlN, AlOx, or TiOx. It may be preferable, in some cases, to fabricate the protective liners 136 from a material having a substantially different etch rate than that of the surrounding materials effect good etch selectivity. The dielectric layer can be deposited with a conformal deposition technique, using any known atomic layer deposition technique, molecular layer deposition techniques, or other known conformal deposition techniques. In an embodiment, the dielectric layer can have a substantially conformal and uniform thickness ranging from about 1 nm to about 3 nm, and ranges there between.

Next, a directional anisotropic etching technique may be used to remove portions of the conformal dielectric layer from horizontal surfaces of the structure 100, while leaving it on the sidewalls of the sidewall spacers 132, the channel nanosheets 108, and the inner spacers 134. For example, a reactive-ion-etching technique may be used to remove portions of the conformal dielectric layer from directly above the substrate 104 and from a top surface of the individual gate hard masks 130 and top surfaces of the sidewall spacers 132. The portions of the conformal dielectric layer remain along opposite sidewalls of the sidewall spacers 132, the channel nanosheets 108, and the inner spacers 134, as illustrated. The directional etching technique may continue until the placeholder cavities 138 are formed in the substrate. Specifically, etching continues until portions of the top semiconductor layer 114 are removed and the placeholder cavities 138 are formed, as illustrated. As a result, the placeholder cavities 138 are arranged between adjacent nanosheet stacks.

Unique to the present invention, the placeholder cavities 138 are created across an entire array of devices, or in some instances, across an entire wafer. Meanwhile in other technologies, the placeholder cavities 138 would be formed only in desired locations.

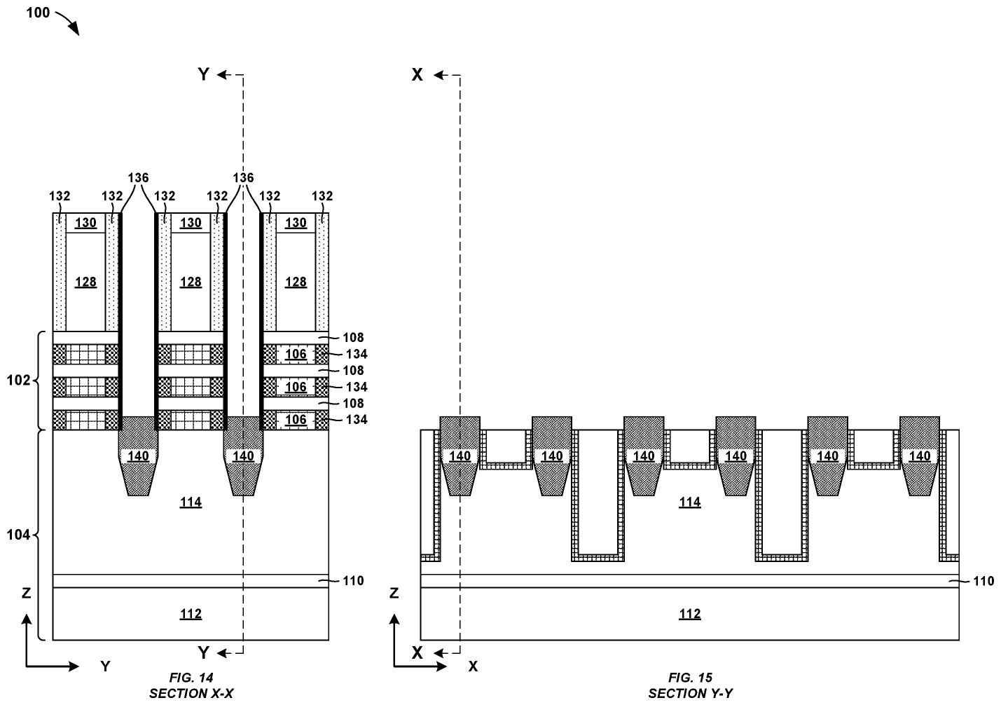

Referring now to FIGS. 14 and 15, a structure 100 is shown after forming sacrificial placeholders 140 in the placeholder cavities 138 according to an embodiment of the invention. FIG. 15 depicts a cross-sectional view of the structure 100 shown in FIG. 15 taken along line X-X, and FIG. 15 depicts a cross-sectional view of the structure 100 shown in FIG. 14 taken along line Y-Y.

The placeholder cavities 138 are filled with a sacrificial placeholder material according to known techniques. After, the sacrificial placeholder material is recessed to create the sacrificial placeholders 140 according to known techniques. In an embodiment, the sacrificial placeholder material is SiC, SiOC deposited using, for example, chemical vapor deposition (CVD) or plasma enhanced CVD (PECVD) and subsequently recessed using, for example, reactive ion etching (RIE). Other suitable deposition and recessing techniques may be used provided they do not induce a physical or chemical change to the channel nanosheets 108. Finally, the sacrificial placeholders 140 can also be referred to as a dielectric sacrificial placeholders 140 or dielectric placeholders 140. In another embodiment, the sacrificial placeholders 140 are a semiconductor material, such as SiGe, formed by an epitaxial deposition technique.

As previously described above, since the placeholder cavities 138 are created across an entire array of devices, or in some instances, across an entire wafer, so are the sacrificial placeholders 140, as illustrated. In contrast, sacrificial placeholders 140 in other technologies are generally formed only in desired locations. Forming the sacrificial placeholders 140 everywhere provides unique advantages, such as, for example, enables uniform placeholder epi and source/drain epi growth with less loading effect.

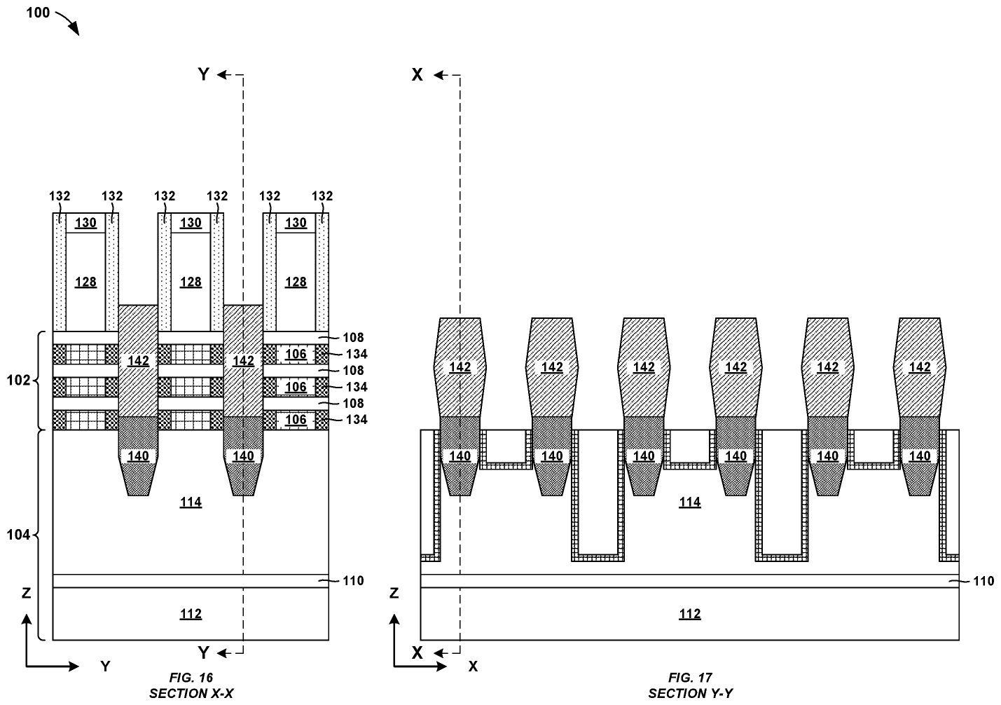

Referring now to FIGS. 16 and 17, a structure 100 is shown after removing the protective liners 136 and forming source drain regions 142 according to an embodiment of the invention. FIG. 16 depicts a cross-sectional view of the structure 100 shown in FIG. 17 taken along line X-X, and FIG. 17 depicts a cross-sectional view of the structure 100 shown in FIG. 16 taken along line Y-Y.

First, remaining portions of the protective liners 136 are removed according to known techniques. Specifically, remaining portions of the protective liners 136 are removed using known as wet or dry etching techniques. In an embodiment, the remaining portions of the protective liners 136 are removed using an anisotropic etch such as, for example, reactive ion etching.

Next, the source drain regions 142 are formed using an epitaxial layer growth process on the exposed ends of the channel nanosheets 106 according to known techniques. Typically, in-situ doping is used to dope the source drain regions 142, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

Of note, because the sacrificial placeholders 140 and the source drain regions 142 are formed within the same trench or opening, they are considered self-aligned. Said differently a relative width of the sacrificial placeholders 140 is approximately equal to a relative width of the source drain regions as measured in the y-direction. As such, the sacrificial placeholders 140 are immediately below the source drain regions 142, as illustrated.

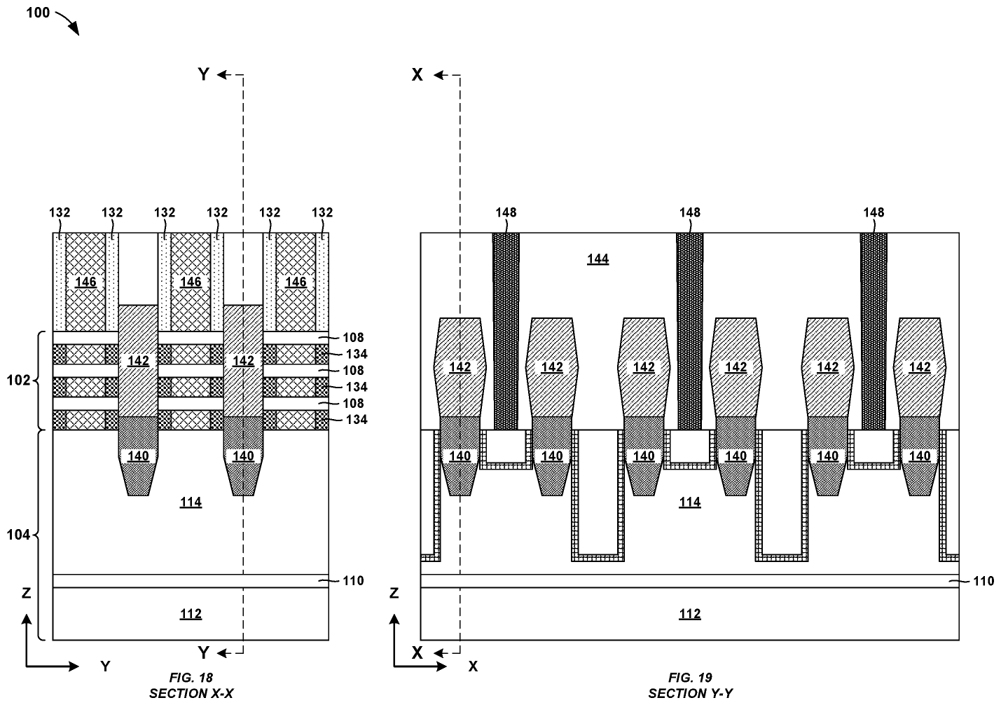

Referring now to FIGS. 18 and 19, a structure 100 is shown after forming a dielectric layer 144, forming gate structures 146, and gate cut insulators 148 according to an embodiment of the invention. FIG. 18 depicts a cross-sectional view of the structure 100 shown in FIG. 19 taken along line X-X, and FIG. 19 depicts a cross-sectional view of the structure 100 shown in FIG. 18 taken along line Y-Y.

The dielectric layer 144 is formed by blanket depositing an interlayer dielectric material over the structure 100 according to known techniques. Specifically, the dielectric layer 144 is formed on and around the source drain regions 142 and substantially fills the remaining space between adjacent nanosheet stacks, as illustrated.

The dielectric layer 144 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 144. Using a self-planarizing dielectric material as the dielectric layer 144 can avoid the need to perform a subsequent planarizing step.

After the dielectric layer 144 is formed, the structure is polished according to known techniques, such as, for example, chemical mechanical polishing techniques. Specifically, the dielectric layer 144, the gate spacers 132, and the gate masks 130 are polished until a topmost surface of the dielectric layer 144 is flush, or substantially flush, with topmost surfaces of the gate spacers 132 and the sacrificial gates 128. In doing so, the gate masks 130 are completely removed.

Next, the sacrificial gates 128 and the sacrificial nanosheets 106 are selectively removed according to known techniques. First, the sacrificial gates 128 are etched and removed selective to the gate spacers 132 and the nanosheet layers 102 according to known techniques. Next, the sacrificial nanosheets 106 are etched and removed selective to the channel nanosheets 108 and the inner spacers 134 according to known techniques. Doing so is made possible by the different concentrations of germanium. In this case, the layers with germanium are removed selective to layers without germanium.

Next, the gate structures 146 are formed according to known techniques. First, a gate dielectric (not shown) is conformally deposited directly on exposed surfaces of the structure 100 within the gate cavities or openings and spaces left by removing the sacrificial gates 128 and the sacrificial nanosheets 106 according to known techniques. For example, the gate dielectric is conformally deposited on exposed surfaces of the channel nanosheets 108 and the inner spacers 134.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaALO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, a work function metal (not shown) is conformally deposited on the first gate dielectric formed within the gate cavities according to known techniques. In at least one embodiment, the work function metal is made of the same conductive material across the entire structure. In at least another embodiment, the first function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium carbon (TiC), titanium aluminum (TiAl), titanium aluminum carbon (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, gate metal or contact metal, is deposited directly on the work function metal, and fills the gate cavities. The first gate metal may include any suitable conductive material, such as, for example, copper, ruthenium, aluminum, tungsten, cobalt, or alloys thereof. After, excess conductive material can be polished using known techniques.

Next, a gate cut mask (not shown) is formed over the structure 100 and exposed portions of the dielectric layer 144 are removed and then filled with a dielectric insulating material to form the gate cut insulators 148. The gate cut mask, and subsequently the gate cut insulators 148 are present between, and separates, adjacent gate structures 146 from one another in the x-direction.

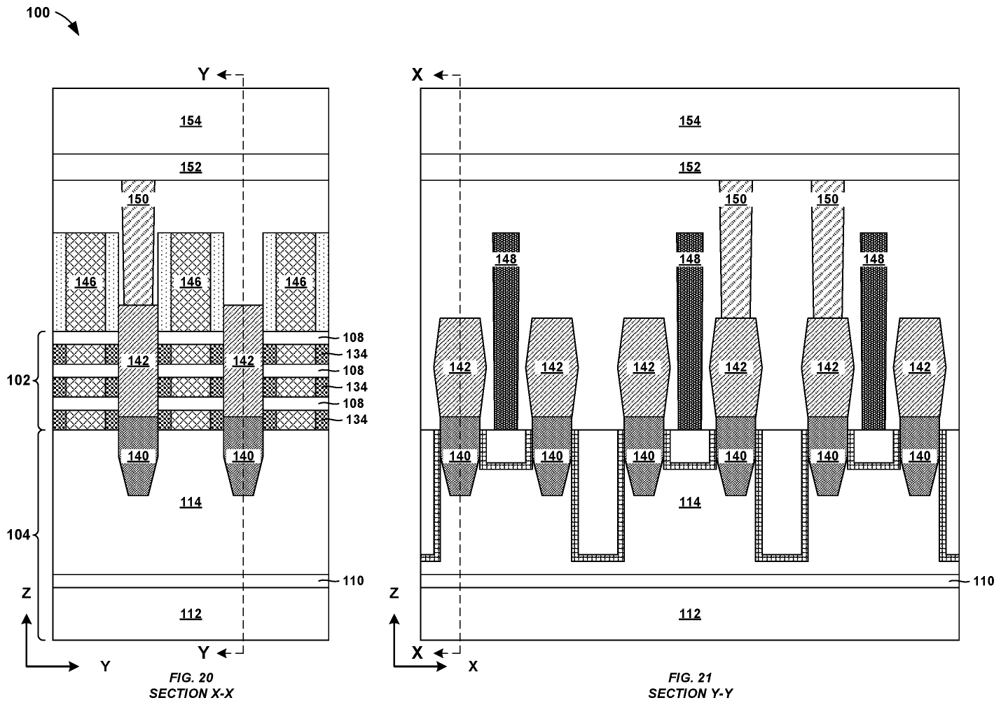

Referring now to FIGS. 20 and 21, a structure 100 is shown after forming source drain contacts 150, a middle-of-line and back-end-of-line 152, and attaching a carrier wafer 154 according to an embodiment of the invention. FIG. 20 depicts a cross-sectional view of the structure 100 shown in FIG. 21 taken along line X-X, and FIG. 21 depicts a cross-sectional view of the structure 100 shown in FIG. 20 taken along line Y-Y.

First, additional interlayer dielectric material is deposited according to known techniques. The dielectric layer 144 illustrated in the figures includes the additional interlayer dielectric material. Portions of the dielectric layer 144 are then removed to created contact openings and expose the source drain regions 142. Next, the contact openings are filled with a conductive material to form the source drain contacts 150 according to known techniques. The source drain contacts 150 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. In some embodiments, the source drain contacts 150 do not contact the gate spacers 132, as illustrated in FIG. 20. In other embodiments, the source drain contacts 150 are self-aligned to the gate spacers 132 and directly contact the gate spacers 132.

The middle-of-line and back-end-of-line 152 (hereinafter MOL/BEOL 152) is formed and the carrier wafer 154 is secured to a top of the structure 100 according to an embodiment of the invention. After forming the source drain contacts 150, the MOL/BEOL 152 is subsequently formed according to known techniques. Next, the carrier wafer 154 is attached, or removably secured, to the MOL/BEOL 152. In general, and not depicted, the carrier wafer 154 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 154 according to known techniques.

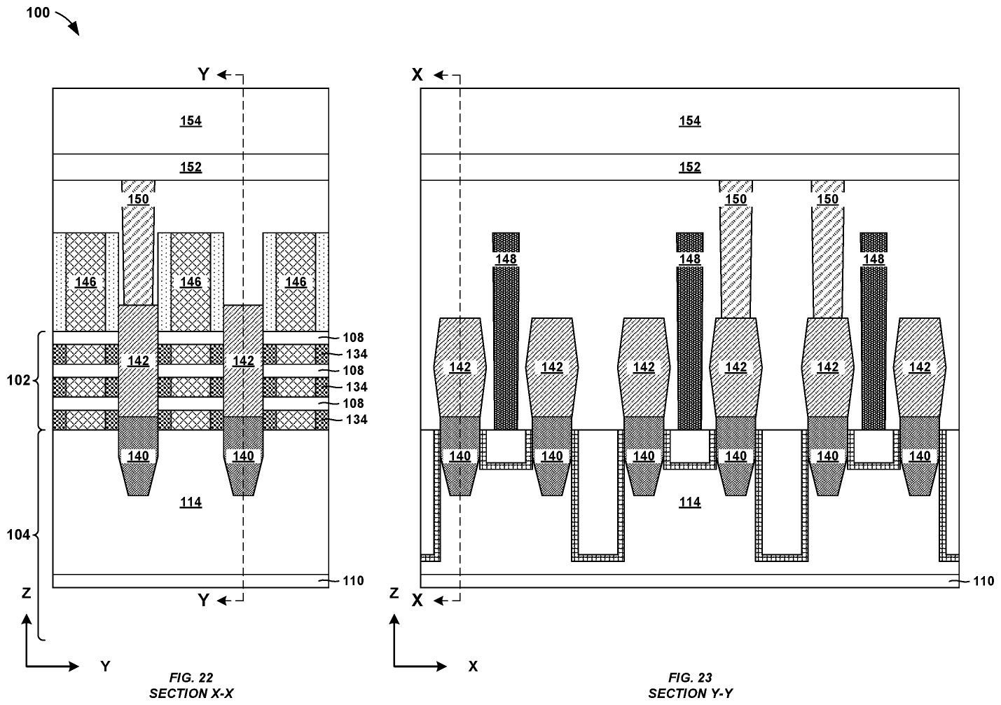

Referring now to FIGS. 22 and 23, a structure 100 is shown after flipping the assembly and recessing the substrate 104 according to an embodiment of the invention. FIG. 22 depicts a cross-sectional view of the structure 100 shown in FIG. 23 taken along line X-X, and FIG. 23 depicts a cross-sectional view of the structure 100 shown in FIG. 22 taken along line Y-Y.

The structure 100 is flipped 180 degrees to prepare for backside processing. In general, backside processing includes fabrication or processing of the structure 100 opposite the active device and wiring layers. Next, the substrate 104 is recessed according to known techniques. Specifically, the base substrate 112 is recessed or completely removed to expose the etch stop layer 110, as shown.

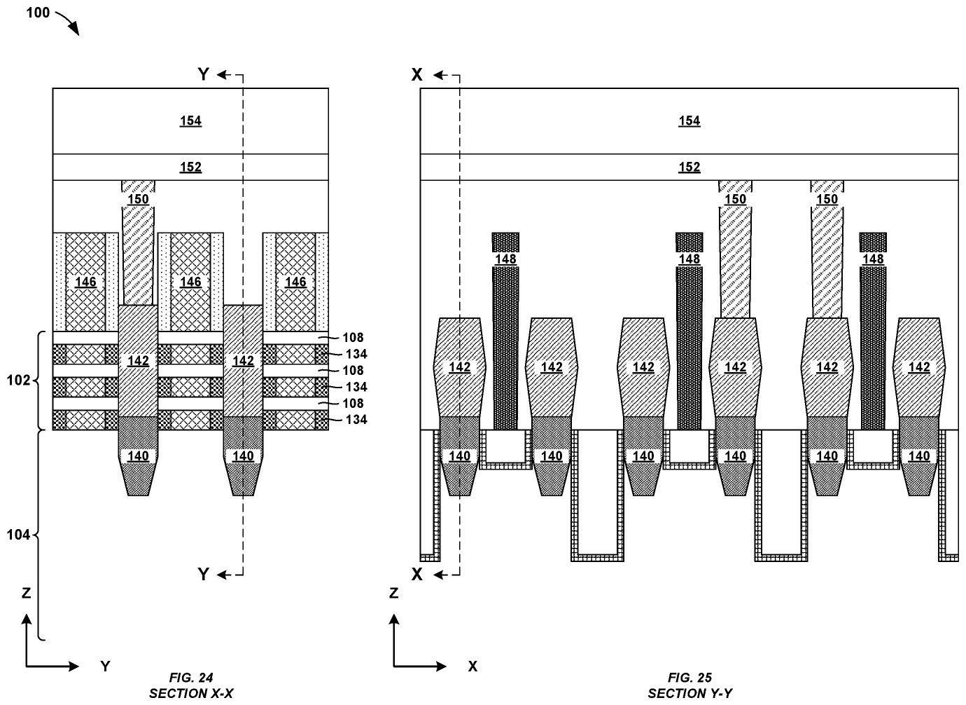

Referring now to FIGS. 24 and 25, a structure 100 is shown after removing remaining portions of the substrate 104 according to an embodiment of the invention. FIG. 24 depicts a cross-sectional view of the structure 100 shown in FIG. 25 taken along line X-X, and FIG. 25 depicts a cross-sectional view of the structure 100 shown in FIG. 24 taken along line Y-Y.

The etch stop layer 110 and the top semiconductor layer 114 are selectively removed according to known techniques. Specifically, the etch stop layer 110 is removed selective to the top semiconductor layer 114, and then the top semiconductor layer 114 is removed selective to the STI regions 124, 126, the sacrificial placeholders 140, the gate structures 146, and the inner spacers 134, as illustrated.

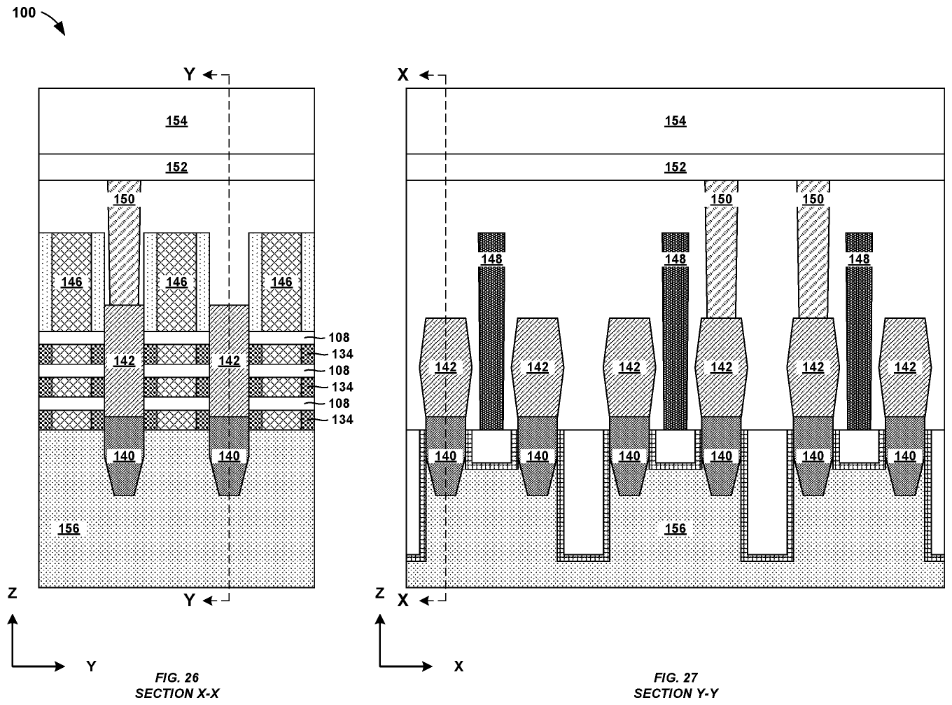

Referring now to FIGS. 26 and 27, a structure 100 is shown after forming a backside dielectric layer 156 according to an embodiment of the invention. FIG. 26 depicts a cross-sectional view of the structure 100 shown in FIG. 27 taken along line X-X, and FIG. 27 depicts a cross-sectional view of the structure 100 shown in FIG. 26 taken along line Y-Y.

The backside dielectric layer 156 is formed by blanket depositing an interlayer dielectric material over the structure 100 according to known techniques. Specifically, the backside dielectric layer 156 is formed on, and covers, the sacrificial placeholders 140, the STI regions 124, 126, and exposed bottom surfaces of the nanosheet stacks, as illustrated.

The backside dielectric layer 156 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the backside dielectric layer 156. Using a self-planarizing dielectric material as the backside dielectric layer 156 can avoid the need to perform a subsequent planarizing step.

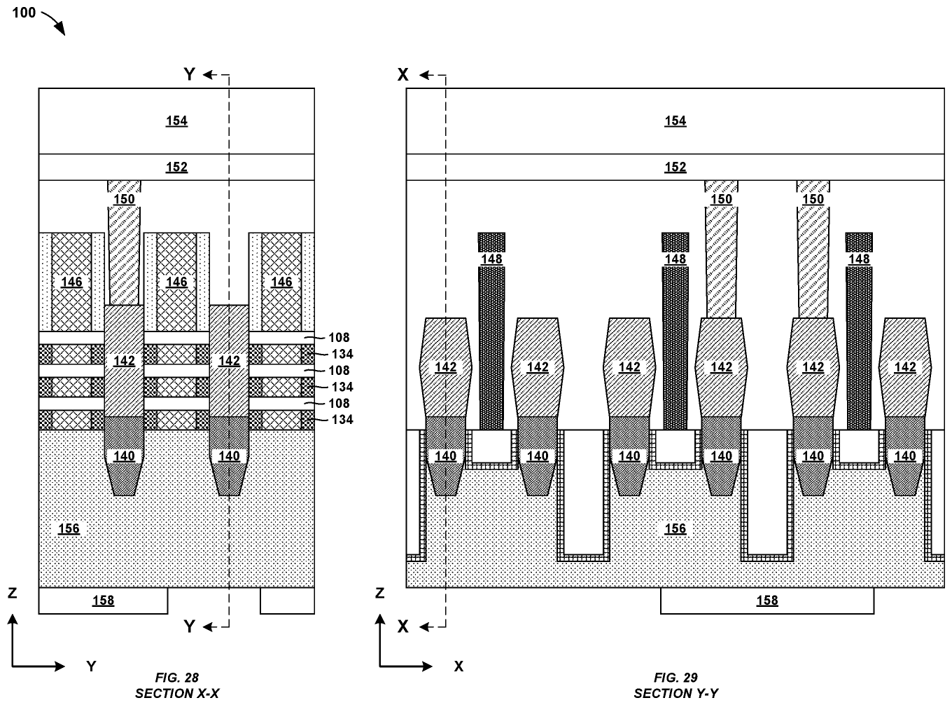

Referring now to FIGS. 28 and 29, a structure 100 is shown after forming a backside contact mask 158 according to an embodiment of the invention. FIG. 28 depicts a cross-sectional view of the structure 100 shown in FIG. 29 taken along line X-X, and FIG. 29 depicts a cross-sectional view of the structure 100 shown in FIG. 28 taken along line Y-Y.

The backside contact mask 158 is deposited and subsequently patterned to expose certain portions of the structure 100 according to known techniques. The backside contact mask 158 can be an organic planarization layer (OPL) or a layer of material that is capable of being planarized or etched by known techniques. In an embodiment, for example, the backside contact mask 158 can be an amorphous carbon layer able to withstand subsequent processing temperatures. The backside contact mask 158 can preferably have a thickness sufficient to cover existing structures. After deposition of the backside contact mask 158, a dry etching technique is applied to pattern the backside contact mask 158 according to known techniques. Specifically, the backside contact mask 158 is patterned to expose portions of the structure 100 generally aligned with certain of the source drain regions 142.

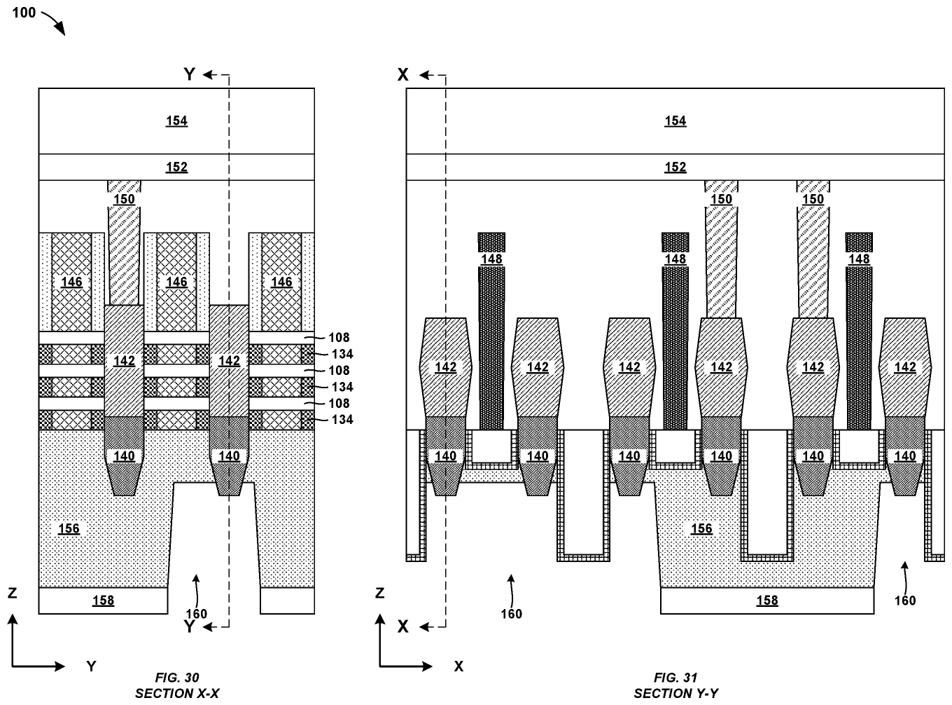

Referring now to FIGS. 30 and 31, a structure 100 is shown after forming backside contact trenches 160 according to an embodiment of the invention. FIG. 30 depicts a cross-sectional view of the structure 100 shown in FIG. 31 taken along line X-X, and FIG. 31 depicts a cross-sectional view of the structure 100 shown in FIG. 30 taken along line Y-Y.

The pattern created by the backside contact mask 158 is transferred into the backside dielectric layer 156, as illustrated. Specifically, portions of the backside dielectric layer 156 are etched or removed selective to the STI regions 124, 126 and the sacrificial placeholders 140 to create the backside contact trenches 160. According to an embodiment, the portions of the backside dielectric layer 156 can be removed using a silicon RIE process. After etching, the remaining portions of the backside contact mask 158 are removed according to known techniques, for example, by ashing.

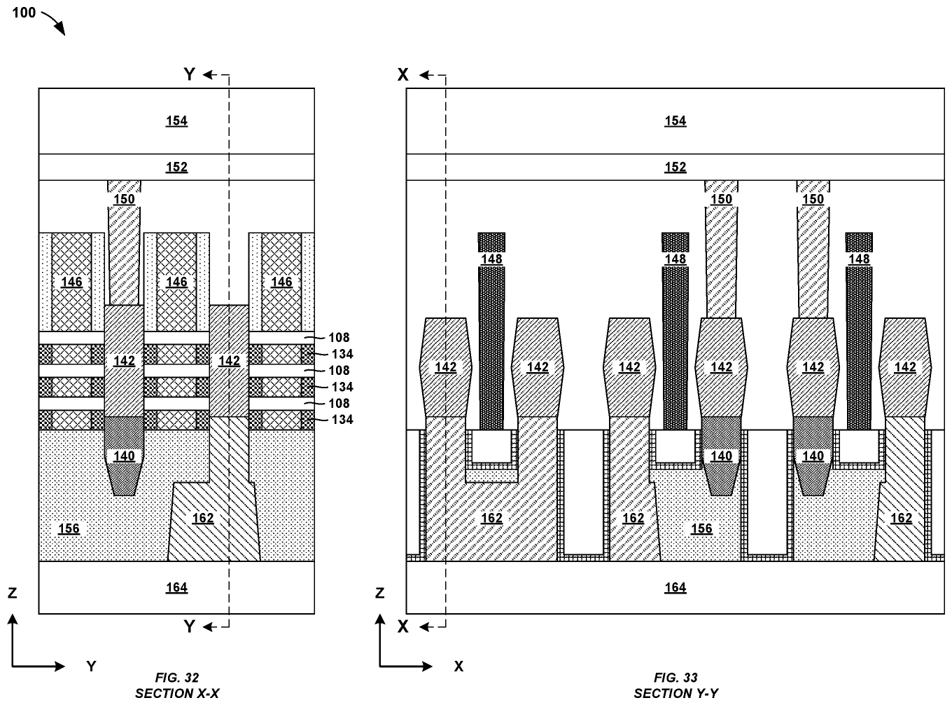

Referring now to FIGS. 32 and 33, a structure 100 is shown after removing exposed portions of the sacrificial placeholders 140, forming backside contact structures 162 and backside wiring layers 164 according to an embodiment of the invention. FIG. 32 depicts a cross-sectional view of the structure 100 shown in FIG. 33 taken along line X-X, and FIG. 33 depicts a cross-sectional view of the structure 100 shown in FIG. 32 taken along line Y-Y.

First, the portions of the sacrificial placeholders 140 exposed within the backside contact trenches 160 are selectively removed according to known techniques. Specifically, only exposed portions of the sacrificial placeholders 140 are etched or removed selective to the STI regions 124, 126, dielectric layer 156, and the source drain regions 142. For example, in an embodiment, anisotropic etching techniques such as, for example, reactive ion etching are used to remove the exposed portions of the sacrificial placeholders 140. Critical to the present invention, portions of the source drain regions 142 are exposed after removing portions of the sacrificial placeholders 140 to ensure direct contact with the backside contact structures 162. Of note, despite sacrificial placeholders 140 generally being everywhere, as previously described, only certain of the sacrificial placeholders 140 are removed from within the backside contact trenches 160.

The backside contact trenches 160 are then filled with a conductive material to form the backside contact structures 162 according to known techniques. The backside contact structures 162 may include any suitable conductive material, such as, for example, copper, ruthenium, aluminum, tungsten, cobalt, or alloys thereof. In some embodiments, a metal silicide is formed at the bottom of the backside contact trenches 160 prior to filling them with the conductive material. After filling, excess conductive material can be polished using known techniques until bottommost surfaces of the backside contact structures 162 are flush, or substantially flush, with bottommost surfaces of the second STI regions 126 and the backside dielectric layer 156, as illustrated.

Unique to the present invention, the first shallow trench isolation regions 124 allow some of the backside contact structures 162 to be merged for two adjacent devices having the same type. Meanwhile, the first shallow trench isolation regions 126 maintain isolation between the backside contact structures 162 of adjacent devices of different types and thereby prevent shorts. Additionally, the backside contact structures 162 are self-aligned to corresponding source drain regions (142), as illustrated.

After forming the backside contact structures 162, the backside wiring layers 164 are subsequently formed according to known techniques. It is noted, the backside wiring layers 164 may include, for example, backside power rails and backside power delivery network(s).

With continued reference to FIGS. 32 and 33, and according to an embodiment, the structure 100 includes first shallow trench isolation regions and second shallow trench isolation regions, where the second shallow trench isolation regions are deeper than the first shallow trench isolation regions, and backside contact structures in direct contact with and physically separated by at least one of the second shallow trench isolation regions.

With continued reference to FIGS. 32-33, and according to an embodiment, the structure 100 further includes dielectric placeholders in direct contact with and physically separated by at least one of the second shallow trench isolation regions.

With continued reference to FIGS. 32-33, and according to an embodiment, the structure 100 further includes dielectric placeholders immediately below and self-aligned to corresponding source drain regions.

With continued reference to FIGS. 32-33, and according to an embodiment, bottommost surfaces of the second shallow trench isolation regions are substantially flush with bottommost surfaces of the backside contact structures.

With continued reference to FIGS. 32-33, and according to an embodiment, the backside contact structures comprise a merged contact structure having opposite sidewalls in direct contact with two of the second shallow trench isolation regions, and an un-merged contact structure having only one sidewall in direct contact with only one of the second shallow trench isolation regions.

With continued reference to FIGS. 32-33, and according to an embodiment, the backside contact structures are self-aligned to corresponding source drain regions.

With continued reference to FIGS. 32-33, and according to an embodiment, the first shallow trench isolation regions are physically arranged between devices of the same type, and the second shallow trench isolation regions are physically arranged between devices of different types.

With continued reference to FIGS. 32 and 33, and according to an embodiment, the structure 100 includes first shallow trench isolation regions and second shallow trench isolation regions, where the second shallow trench isolation regions are deeper than the first shallow trench isolation regions, a first backside contact structure in direct contact with at least one of the first shallow trench isolation regions and at least one of the second shallow trench isolation regions, and a second backside contact structure in direct contact with at least one of the first shallow trench isolation regions and at least one of the second shallow trench isolation regions, where at least one of the second shallow trench isolation regions physically separates the first backside contact structure from the second backside contact structure.

With continued reference to FIGS. 32 and 33, and according to an embodiment, the structure 100 includes a first shallow trench isolation region arranged between two N-type transistor devices, a second shallow trench isolation region arranged between two P-type transistor devices, a third shallow trench isolation region arranged between and the two N-type devices and the two P-type transistor devices, where the third shallow trench isolation region is deeper than both the first shallow trench isolation region and the second shallow trench region, a first backside contact structure in direct contact with both of the two N-type transistor devices, and a second backside contact structure in direct contact with at least one of the two P-type transistor devices.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
first shallow trench isolation regions and second shallow trench isolation regions, wherein the second shallow trench isolation regions are deeper than the first shallow trench isolation regions; and
backside contact structures in direct contact with and physically separated by at least one of the second shallow trench isolation regions.

2. The semiconductor structure according to claim 1, further comprising:
dielectric placeholders in direct contact with and physically separated by at least one of the second shallow trench isolation regions.

3. The semiconductor structure according to claim 1, further comprising:
dielectric placeholders immediately below and self-aligned to corresponding source drain regions.

4. The semiconductor structure according to claim 1, wherein bottommost surfaces of the second shallow trench isolation regions are substantially flush with bottommost surfaces of the backside contact structures.

5. The semiconductor structure according to claim 1, wherein the backside contact structures comprise a merged contact structure having opposite sidewalls in direct contact with two of the second shallow trench isolation regions, and an un-merged contact structure having only one sidewall in direct contact with only one of the second shallow trench isolation regions.

6. The semiconductor structure according to claim 1, wherein the backside contact structures are self-aligned to corresponding source drain regions.

7. The semiconductor structure according to claim 1, wherein the first shallow trench isolation regions are physically arranged between devices of the same type, and the second shallow trench isolation regions are physically arranged between devices of different types.

8. A semiconductor structure comprising:
first shallow trench isolation regions and second shallow trench isolation regions, wherein the second shallow trench isolation regions are deeper than the first shallow trench isolation regions;
a first backside contact structure in direct contact with at least one of the first shallow trench isolation regions and at least one of the second shallow trench isolation regions; and
a second backside contact structure in direct contact with at least one of the first shallow trench isolation regions and the at least one of the second shallow trench isolation regions, wherein the at least one of the second shallow trench isolation regions physically separates the first backside contact structure from the second backside contact structure.

9. The semiconductor structure according to claim 8, further comprising:
dielectric placeholders in direct contact with and physically separated by at least one of the second shallow trench isolation regions.

10. The semiconductor structure according to claim 8, further comprising:
dielectric placeholders immediately below and self-aligned to corresponding source drain regions.

11. The semiconductor structure according to claim 8, wherein bottommost surfaces of the second shallow trench isolation regions are substantially flush with a bottommost surface of the first backside contact structure and a bottommost surface of the second backside contact structure.

12. The semiconductor structure according to claim 8, wherein the first backside contact structure comprises a merged contact structure having opposite sidewalls in direct contact with two of the second shallow trench isolation regions, and wherein the second backside contact structure comprise an un-merged contact structure having only one sidewall in direct contact with only one of the second shallow trench isolation regions.

13. The semiconductor structure according to claim 8, wherein both the first backside contact structure and the second backside contact structure are self-aligned to corresponding source drain regions.

14. The semiconductor structure according to claim 8, wherein the first shallow trench isolation regions are physically arranged between devices of the same type, and the second shallow trench isolation regions are physically arranged between devices of different types.

15. A semiconductor structure comprising:
a first shallow trench isolation region arranged between two N-type transistor devices;
a second shallow trench isolation region arranged between two P-type transistor devices;
a third shallow trench isolation region arranged between and the two N-type devices and the two P-type transistor devices, wherein the third shallow trench isolation region is deeper than both the first shallow trench isolation region and the second shallow trench region;
a first backside contact structure in direct contact with both of the two N-type transistor devices; and
a second backside contact structure in direct contact with at least one of the two P-type transistor devices.

16. The semiconductor structure according to claim 15, further comprising:
dielectric placeholders in direct contact with and physically separated by the second shallow trench isolation region.

17. The semiconductor structure according to claim 15, further comprising:
dielectric placeholders immediately below and self-aligned to corresponding source drain regions.

18. The semiconductor structure according to claim 15, wherein bottommost surfaces of the first shallow trench isolation region, the second first shallow trench isolation region, the third first shallow trench isolation region, the first backside contact structure, and the second backside contact structure are substantially flush with one another.

19. The semiconductor structure according to claim 15, wherein the first backside contact structure comprises a merged contact structure having sidewalls in direct contact with a sidewall of the first shallow trench isolation region and a sidewall of the third shallow trench isolation region, respectively, and wherein the second backside contact structure comprises an un-merged contact structure having opposite sidewalls in direct contact with a sidewall of the third shallow trench isolation region and a sidewall of the second shallow trench isolation region, respectively.

20. The semiconductor structure according to claim 15, wherein the first shallow trench isolation regions are physically arranged between devices of the same type, and the second shallow trench isolation regions are physically arranged between devices of different types.
